(19) United States
(12) Patent Application Publication
(10) Pub. No.: US 2008/0100265 A1
(43) Pub. Date: May 1, 2008

(54) BATTERY MANAGEMENT SYSTEM AND DRIVING METHOD THEREOF

(75) Inventors: Gye-Jong LIM, Yongin-si (KR); Soo-Seok Choi, Yongin-si (KR); Young-Jo Lee, Yongin-si (KR); Yong-Jun Tae, Yongin-si (KR); Beom-Gyu Kim, Yongin-si (KR); Ho-Young Park, Yongin-si (KR); Han-Seok Yun, Yongin-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/852,575

(22) Filed: Sep. 10, 2007

(30) Foreign Application Priority Data
Nov. 1, 2006 (KR) 10-2006-0107224

(51) Int. Cl. G01R 31/36; H01M 10/44; H02J 7/00

(52) U.S. Cl. 320/134

(57) ABSTRACT

A battery management system to set an OCV setting of a battery, and a driving method thereof. The battery management system includes a sensing unit and a main control unit (MCU). The sensing unit measures a voltage of a battery. The MCU controls charging/discharging of the voltage of the battery, generates charge/discharge pulse pattern waveforms, measures and stores maximum and minimum voltages value of at least one pulse pattern among the charge/discharge pulse pattern waveforms, and sets an average of the measured voltage to an OCV setting from which an SOC is determined. The battery management system estimates the SOC while a vehicle is operating.

### CROSS-REFERENCE TO RELATED APPLICATIONS

This application claims the benefit of Korean Patent Application No. 2006-107224, filed Nov. 1, 2006, in the Korean Intellectual Property Office, the disclosure of which is incorporated herein by reference.

### BACKGROUND OF THE INVENTION

1. Field of the Invention

Aspects of the present invention relate to a battery management system. More particularly, aspects of the present invention relate to a battery management system that can be used in a vehicle using electrical energy.

2. Description of the Related Art

Vehicles with internal combustion engines using gasoline or diesel have caused serious air pollution. Accordingly, various attempts to develop electric or hybrid vehicles have recently been made to reduce such air pollution.

An electric vehicle uses an electric motor operating by electrical energy output from a battery. Since the electric vehicle generally uses a battery formed of at least one battery pack including a plurality of rechargeable/dischargeable (or secondary) cells, there is merit in that the electric vehicle generates no emission gases and produces less noise.

“Hybrid vehicle” commonly refers to a gasoline-electric hybrid vehicle that uses gasoline to power an internal-combustion engine and a battery to power an electric motor. Recently, hybrid vehicles using an internal-combustion engine and fuel cells and hybrid vehicles using a battery and fuel cells have been developed. The fuel cells directly produce electrical energy through a chemical reaction between hydrogen and oxygen, which are continuously provided.

Since battery performance directly affects the performance of the vehicle using electrical energy, it is required that each battery cell has great performance. Also, a battery management system (BMS) is necessary to measure a voltage and a current of the overall battery to efficiently manage charging/discharging operations of each battery cell therein.

In general, the battery management system needs to measure an accurate open circuit voltage (OCV) so as to measure an accurate SOC. When a vehicle is driven at a constant speed or is stopped, and a charging and discharging operation of the battery is not performed, the OCV may not be accurately measured as polarization and internal resistance in the battery, is generated. A length of time to correct the polarization is required to accurately measure the OCV. However, it is difficult to guarantee such a time when a hybrid vehicle is driven. Accordingly, an error in measuring the OCV measured after only a short time or before the correction of the polarization may cause an error in the calculation of the SOC.

The above information disclosed in this Background section is only for enhancement of understanding of the background of the invention and therefore it may contain information that does not form the prior art that is already known in this country to a person of ordinary skill in the art.

### SUMMARY OF THE INVENTION

Aspects of the present invention have been made in an effort to provide a battery management system having advantages of estimating an accurate state of charge (SOC) by accurately measuring an open circuit voltage (OCV), and a driving method thereof.

A battery management system according to an embodiment of the present invention includes a sensing unit and a main control unit (MCU). The sensing unit measures a voltage of a battery. The MCU controls charge/discharge of the voltage of the battery, generates charge/discharge pulse pattern waveforms, measures a voltage value of at least one pulse pattern among the charge/discharge pulse pattern waveforms, and sets an average of the measured voltage to an open circuit voltage (OCV). The MCU generates a battery charge/discharge pulse pattern waveform by controlling charge/discharge of the voltage of the battery when a state of charge (SOC) of the battery becomes a predetermined level after the battery is fully charged or fully discharged. Herein, the battery charge/discharge pulse pattern waveform is formed of a plurality of pulse patterns, each formed by repeating charge and discharge of the battery once.

In addition, the MCU includes a pulse pattern controller and an OCV setting unit. The pulse pattern controller counts the plurality of battery pulse patterns and stores a maximum peak voltage and a minimum peak voltage of a detected pulse pattern including at least the last pulse among the plurality of counted pulse patterns. The OCV setting unit calculates an average value of the maximum peak voltage and the minimum peak voltage of the detected pulse pattern, and sets the average value to an OCV.

A driving method according to another embodiment of the present invention is provided to a battery management system for setting an OCV of a battery. The driving method includes: determining whether a battery is fully charged or fully discharged, and maintaining a state of charge (SOC) of a battery at a constant level; controlling charge/discharge of the battery, generating a plurality of battery charge/discharge pulse patterns, and counting the pulse patterns; and calculating an average value of a maximum peak voltage and a minimum peak voltage of a detected pulse pattern including at least the last pulse, and setting the average value to an OCV.

In addition, the battery charge/discharge pulse pattern waveform is formed of a plurality of pulse patterns generated by repeating charge and discharge of the battery once.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows a diagram representing a battery, a battery management system (BMS), and peripheral devices of the BMS;

FIG. 2 shows a schematic diagram of the MCU of the BMS of FIG. 1; and

FIG. 3 is a flowchart representing a driving method of the BMS according to aspects of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

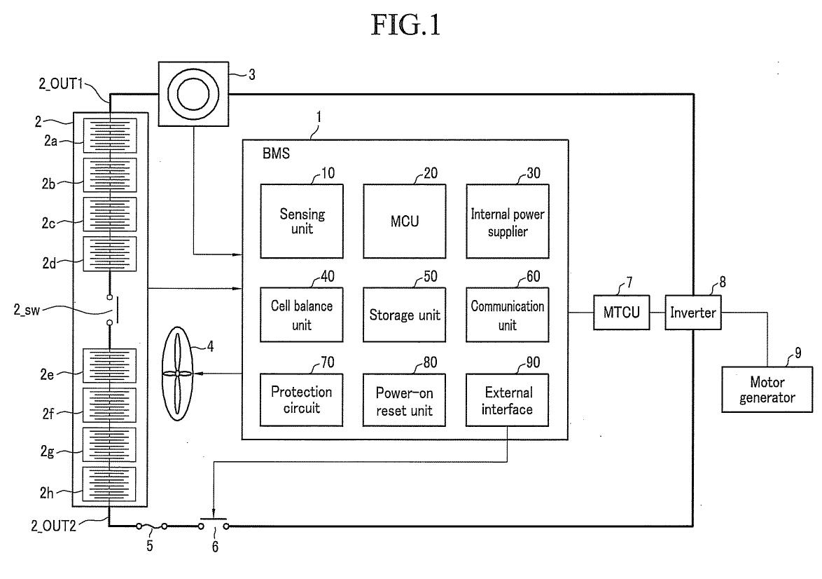

FIG. 1 shows a diagram representing a battery, a battery management system (BMS), and peripheral devices of the BMS according to aspects of the present invention. As shown in FIG. 1, the hybrid electric vehicle system according to aspects of the present invention includes a battery management system 1, a battery 2, a current sensor 3, a cooling fan 4, a fuse 5, a main switch 6, a motor control unit (MTCU) 7, an inverter 8, and a motor generator 9.

The battery 2 includes a plurality of sub-packs 2a to 2h having a plurality of battery cells coupled in series, a first output terminal 2_OUT1, a second output terminal 2_OUT2, and a safety switch 2_SW. The sub-packs 2a to 2h are coupled in series but need not be limited thereto. The sub-packs 2a to 2h may be coupled in series with another component or device disposed therebetween. The safety switch 2_SW is disposed between the sub-pack 2d and the sub-pack 2e. While 8 sub-packs 2a to 2h are exemplified and each sub-pack is a group of a plurality of battery cells according to aspects of the present invention, it is not limited thereto. The battery 2 may include more or fewer sub-packs and battery cells, both of which may be arranged in series or parallel. The safety switch 2_SW is manually turned on/off to guarantee the safety of a worker when performing operations on the battery or replacing the battery. The safety switch 2_SW is provided between the sub-pack 2d and the sub-pack 2e but is not limited thereto. The first output terminal 2_OUT1 and the second output terminal 2_OUT2 are coupled to the inverter 8 via the current sensor 2 and the fuse 5 and the main switch 6, respectively.

The current sensor 3 measures an output current of the battery 2 and outputs the measured output current to a sensing unit 10 of the BMS 1. In further detail, the current sensor 3 may be a hall current transformer (Hall CT) that uses the Hall Effect via a hall element to measure a current and output an analog current signal corresponding to the measured current value. The current sensor 3 may also be an ammeter dispose in a load line or a shunt resistor, which outputs a voltage signal corresponding to a current value through a resistor inserted in the load line.

The cooling fan 4 cools down heat generated by charging and discharging the battery 2 in response to a control signal from the BMS 1. The cooling fan 4 prevents the battery 2 and the charging/discharging efficiency thereof from deteriorating due to temperature increases.

The fuse 5 prevents an overflow current, which may be caused by a short circuit of the battery 2, from being transmitted to the battery 2. That is, when an over-current is generated, the fuse 5 is disconnects or breaks the circuit so as to interrupt the current from overflowing and damaging the battery 2.

The main switch 6 turns the battery 2 on and off in response to the control signals of the BMS1 or control signals of the MTCU 7. The main switch 6 further protects the battery 2 from unusual phenomena, such as an overflowing voltage, an overflowing current, and high temperatures.

The BMS 1 includes a sensing unit 10, a micro control unit (MCU) 20, an internal power supplier 30, a cell balance unit 40, a storage unit 50, a communication unit 60, a protection circuit unit 70, a power-on reset unit 80, and an external interface 90.

The sensing unit 10 measures a voltage of the battery and transmits the measured voltage to the MCU 20. Hereinafter, a voltage at an output terminal of the battery will be referred to as a battery voltage. The sensing unit 10 may also measure a current of the battery 2 and transmit the measured current to the MCU 20.

The MCU 20 determines a state of charge (SOC) of the battery 2 based on the battery voltage transmitted from the sensing unit 10, and generates information that indicates the SOC of the battery 2. Then, the MCU 20 transmits the generated information to the MTCU 7 of the vehicle. In addition, the MCU 20 controls a charge or discharge of the battery 2 to measure an accurate OCV such that a voltage of the battery 2 can have a predetermined number of battery charge/discharge pulse pattern waveforms. Herein, a portion of the predetermined number pulse pattern waveforms is a pulse pattern waveform from which internal resistance and polarization (or polarized resistance) of the battery 2 are eliminated, and the MCU 20 calculates an accurate OCV by using the portion of the pulse pattern waveforms.

Therefore, the MCU 20 sets an OCV setting from which an accurate SOC of the battery is determined by measuring and calculating a voltage of a predetermined number of pulse patterns of a battery charge/discharge pulse pattern waveform generated while the vehicle is being operated.

The internal power supplier 30 supplies power to the BMS 1 by using a backup battery (not shown). The cell balance unit 40 balances the SOC of each cell in the battery 2. That is, cells relatively more charged are discharged, and cells relatively less charged are charged. The storage unit 50 stores data of the current SOC and a current state of health (SOH) when the power source of the BMS 1 is turned off.

The communication unit 60 communicates with the MTCU 7 of the vehicle. The protection circuit unit 70 uses firmware elements to protect the battery 2 from shocks, overflowing currents, and low voltages. The power-on reset unit 80 resets the overall system when the power source of the BMS 1 is turned on. The external interface 90 couples BMS 1 auxiliary devices, such as the cooling fan 4 and the main switch 6, to the MCU 20. While the cooling fan 4 and the main switch 6 are shown as assistance devices for the BMS 1, the BMS 1 is not limited thereto. For example, other auxiliary devices may be included or the present auxiliary devices may be excluded.

The MTCU 7 determines a torque state based on information from an accelerator, a brake, and a vehicle speed, and controls an output of the motor generator 9 so that the output corresponds to torque information. That is, the MTCU 7 controls a switching operation of the inverter 8, and controls the output of the motor generator 9 so that the output corresponds to the torque information. In addition, the MTCU 7 receives the SOC of the battery 2 from the MCU 20 through the communication unit 60, and controls the SOC level of the battery 2 toward a target level (e.g., 55%). For example, when the SOC level transmitted from the MCU 20 is lower than 55%, the MTCU 7 controls a switch to control the inverter 8 so as to output power toward the battery 2 and charge the battery 2. In such case, current flows toward the battery 2 to charge the battery 2. When the SOC level is greater than 55%, the MTCU 7 controls the switch of the inverter 8 to output the power toward the motor generator 9 and discharge the battery 2. In such case, current flows from the battery 2 to power the vehicle.

The inverter 8 controls the battery 2 to be charged or discharged in response to the control signal from the MTCU 7. The motor generator 9 uses the electrical energy of the battery to drive the vehicle based on the torque information transmitted from the MTCU 7.

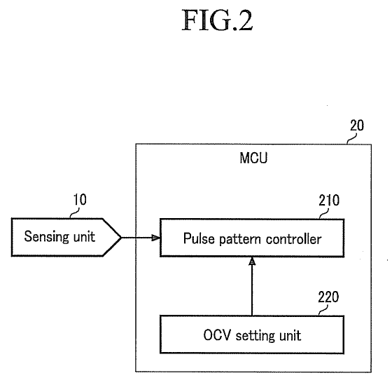

FIG. 2 shows a schematic diagram of the MCU 20 of the BMS 1 of FIG. 1. As shown in FIG. 2, the MCU 20 includes a pulse pattern controller 210 and an OCV setting unit 220.

The pulse pattern controller 210 determines whether the batter 2 is fully charged or fully discharged, and discharges the battery 2 to 60% of the current or previously estimated SOC at a 1 C rate when the battery 2 is fully charged and charges the battery 2 to 60% of the current or previously estimated SOC at a 1 C rate when the battery 2 is fully discharged. Herein, a charge current and a discharge current of a battery are measured in C-rate, which represents the amount of charge/discharge current required for fully charging/discharging the battery within one hour. The pulse pattern controller 210 charges or discharges the battery 2 to 60% of the current or previously estimated SOC at a 1 C rate, and controls the charge/discharge operation of the battery 2 so as to control a voltage of the battery 2 to have a plurality of pulse pattern waveforms.

In this case, each of the plurality of pulse pattern waveforms is formed of a plurality of pulse patterns generated by discharging and charging the battery 2 once, respectively. In addition, the pulse pattern controller 210 eliminates polarization and internal resistance in the battery 2, by using the battery charge/discharge pulse pattern waveform.

The pulse pattern controller 210 controls an SOC of the battery 2 toward a constant level when the battery 2 is fully charged or fully discharged and controls the charge/discharge operation of the battery 2 so as to generate the plurality of battery pulse patterns. In more detail, the pulse pattern controller 210 determines whether the battery 2 is fully charged or fully discharged, discharges the battery 2 to 60% of the current or previously estimated SOC at a 1 C rate when the battery 2 is fully charged, and charges the battery 2 to 60% of the current or previously estimated SOC at a 1 C rate when the battery 2 is fully discharged.

In addition, the pulse pattern controller 210 controls a battery charge/discharge pulse pattern waveform after the battery 2 is charged or discharged. In such case, each of the plurality of battery charge/discharge pulse pattern waveforms is formed of 10 pulse patterns, and each pulse pattern repeats charge and discharge of the battery 2 once. The pulse pattern controller 210 counts a waveform formed of 10 pulses, from the first pulse to the 10th pulse, and stops counting after the pulse pattern controller 210 counts 10 times. Herein, when the number of the pulse waveforms is greater than or equal to 8, the pulse pattern controller stores a maximum peak voltage and a minimum peak voltage among battery voltages of the detected pulse patterns. The detected pulse pattern may include at least the last pulse among the plurality of pulse patterns.

The OCV setting unit 220 adds the maximum peak voltage and the minimum peak voltage of pulse pattern from the 8th detected pulse pattern to the 10th detected pulse pattern transmitted from the pulse pattern controller 210, and calculates an average of the maximum and minimum peak voltages. Then, the OCV setting unit 220 sets the calculated average value to an OCV setting.

According to the OCV setting method of the BMS 1, the OCV setting unit 220 integrates a voltage of a detected pulse pattern that may include at least the last pulse and divides the integration result by time, and then sets a division result to the OCV setting.

That is, the OCV setting unit 220 according to aspects of the present invention may set an average value of maximum and minimum peak voltages of three detected pulse patterns among the plurality of pulse patterns, but this is not restrictive. The OCV setting unit 220 may use the last pulse or the OCV setting unit 220 may average several previous pulses to set the OCV setting. In addition, the described embodiment may be modified in various different ways.

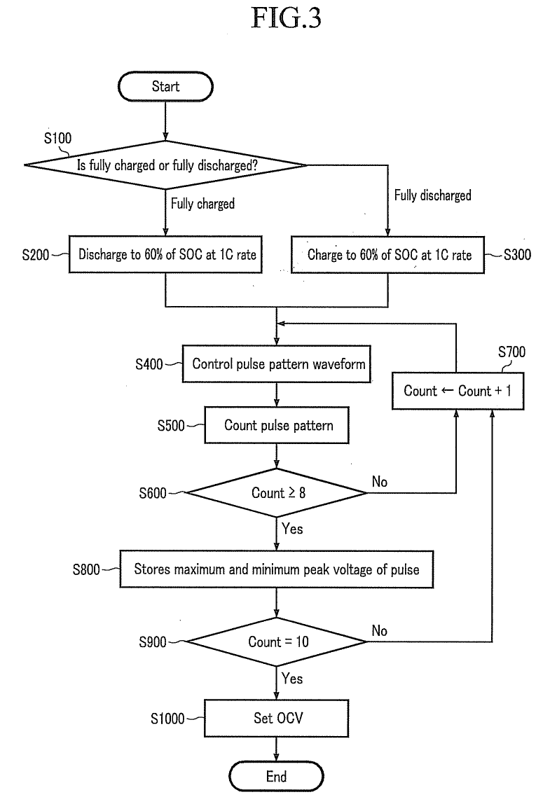

FIG. 3 is a flowchart representing a driving method of the battery management system (BMS 1) according to aspects of the present invention. In operation (S100), the MCU 20 of the BMS 1 determines whether the battery 2 is fully charged or fully discharged. When it is determined in operation (S100) that the battery 2 is fully charged, the MCU 20 discharges the fully charged battery to a predetermined level of 60% of a current or previously estimated SOC at a 1 C rate in operation (S200). When it is determined in operation (S100) that the battery 2 is fully discharged, the MCU 20 charges the fully discharged battery 2 to 60% of the current or previously estimated SOC at a 1 C rate in operation (S300). Herein, a charge current and a discharge current of a battery is measured in C-rate, which represents the amount of charge/discharge current required to fully charge/discharge the battery within one hour. However, the predetermined level need not be 60% of the SOC.

After charging or discharging the battery 2 to the predetermined level (60% of the current or previously SOC), the MCU 20 controls a voltage of the battery 2 applying a battery charge/discharge pulse pattern waveform in operation (S400). In this case, the battery charge/discharge pulse pattern waveform is formed of 10 pulse patterns, wherein each of the 10 pulse patterns charges the battery 2 and discharges the battery 2 once. The MCU 20 counts the battery charge/discharge pulse patterns in operation (S500). Then, the MCU 20 determines whether it has counted the pulse pattern more than 8 times in operation (S600). When it is determined in operation (S600) that the MCU 20 has counted the pulse pattern fewer than 8 times, the MCU 20 increments the number of counting by 1, in operation (S700). Then, the MCU 20 returns to the operation (S400).

When it is determined in operation (S600) that the MCU 20 has counted the pulse pattern at least 8 times, the MCU 200 sets the 8th pulse pattern to the 10th pulse pattern as detected pulse patterns, and stores a maximum peak voltage and a minimum peak voltage of each pulse pattern of the detected pulse patterns in operation (S800). Then, whether counting of the pulse pattern has been performed 10 times is determined in operation (S900). When a result of the determination in operation (S900) shows that the counting of the pulse pattern has been performed less than 10 times, the counting of the pulse pattern is performed one more time and incremented in operation (S700). Then, the process is returned to operation (S400).

When a result of the determination in operation (S900) shows that the counting of the pulse pattern has been performed 10 times, the MCU 200 calculates an average value of the maximum peak voltages and the minimum peak voltages from the detected pulse patterns stored in operation (S800) and the average value (of the maximum and minimum voltages) is set as the OCV setting, in operation (S1000). The OCV setting is then used to estimate the SOC of the battery 2.

Although the driving method is described as averaging the maximum and minimum peak voltages of the 8th through 10th pulse patterns, the MCU 200 is not limited thereto. For example, the OCV setting may be determined by only averaging the minimum peak voltages of the 8th through 10th pulse patterns. Or, only the maximum and minimum peak voltages of the 10th pulse pattern may be averaged to determine the OCV setting from which the SOC of the battery 2 is determined.

As described, the battery management system and the driving method according to aspects of the present invention use a detected pulse pattern to set an OCV setting from which a more accurate SOC may be estimated. The battery management system determines whether the battery is in the fully-charged state or in the fully-discharged state, and charges or discharges the battery to 60% of a current or previously estimated SOC at a 1 C rate according to a result of the determination. Then, the battery management system controls a charge/discharge pulse pattern waveform of the battery and counts a pulse pattern. A maximum peak voltage and a minimum peak voltage of each counted pulse pattern is stored, and an average value of maximum peak voltages and the minimum peak voltages of the 8th counted pulse pattern to the 10th counted pulse pattern is calculated. The calculated average value is set as the OCV setting.

According to aspects of the present invention, an accurate OCV can be set while the vehicle is operating and/or accelerating or while the battery is under a load. Accordingly, the battery management system and the driving method of the battery management system can measure an accurate SOC.

In addition, errors in SOC estimation can be reduced by reducing an error that may be generated when setting an OCV setting, and therefore overcharge and over-discharge of the battery can be prevented.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A battery management system, comprising:
a sensing unit to measure a voltage of a battery; and
a main control unit (MCU) to control charge/discharge of the voltage of the battery, to generate a charge/discharge pulse pattern waveform comprising a plurality of pulse patterns, to measure at least one voltage value of at least one pulse pattern, and to set an average of the at least one measured voltage value to an open circuit voltage (OCV) setting from which a state of charge (SOC) is estimated,
wherein the sensing unit transmits the at least one measured voltage value to the MCU.

2. The battery management system of claim 1, wherein the MCU generates the battery charge/discharge pulse pattern waveform by controlling the charge/discharge of the voltage of the battery when the SOC of the battery is charged/discharged to a predetermined level after the battery has been fully charged or fully discharged.

3. The battery management system of claim 2, wherein each of the plurality of pulse patterns charges and discharges the battery once.

4. The battery management system of claim 3, wherein the MCU comprises:
a pulse pattern controller to count a number of the pulse patterns and to store a maximum peak voltage and a minimum peak voltage of a detected pulse pattern including at least the last pulse pattern of the counted number of pulse patterns; and
an OCV setting unit to calculate an average value of the maximum peak voltage and the minimum peak voltage of the counted number of pulse patterns, and setting the average value to an OCV setting.

5. A driving method of a battery management system to control the charge/discharge of a battery, the driving method comprising:
determining whether the battery is fully charged or fully discharged;
charging/discharging the battery to a state of charge (SOC) of a predetermined level;
generating a battery charge/discharge pulse pattern waveform comprising a plurality of pulse patterns;
counting the pulse patterns;
calculating an average value of a maximum peak voltage and a minimum peak voltage of at lease one detected pulse pattern including a last pulse pattern; and
setting the average value to an OCV setting.

6. The driving method of claim 5, wherein each of the plurality of pulse patterns charges and discharges the battery once.

7. The driving method of claim 5, further comprising estimating the SOC of the battery from the OCV setting.

8. The driving method of claim 5, wherein the plurality of pulse patterns comprises 10 pulses.

9. The driving method of claim 8, wherein the at least one detected pulse pattern comprises an 8th, a 9th, and the last pulse pattern.

10. The driving method claim 8, wherein the average value comprises an average of the maximum peak voltages and the minimum peak voltages of the 8th, the 9th, and the last pulse pattern.

11. The driving method of claim 5, further comprising storing the maximum peak voltage and the minimum peak voltage of the at least one detected pulse pattern.

12. The driving method of claim 5, wherein the average value comprises an average of all of the maximum peak voltages and the minimum peak voltages of the plurality of pulse patterns.

13. The battery management system of claim 2, wherein the predetermined level is 60% of a previously estimated SOC.

14. The battery management system of claim 1, wherein the MCU measures a maximum peak voltage and a minimum peak voltage of the at least one pulse pattern.

15. The battery management system of claim 14, wherein the average comprises an average of the maximum peak voltage and the minimum peak voltage of the at least one pulse pattern.

16. The battery management system of claim 1, wherein the plurality of pulse patterns comprises 10 pulse patterns.

17. The battery management system of claim 16, wherein the at least one voltage value comprises a maximum peak voltage and a minimum peak voltage of the at least one pulse pattern, and the average comprises an average of the maximum peak voltage and the minimum peak voltage of a 10th pulse pattern.

18. The battery management system of claim 16, wherein the at least one voltage value comprises a maximum peak voltage and a minimum peak voltage of the at least one pulse pattern, and the average comprises an average of the maximum peak voltages and the minimum peak voltages of an 8th, a 9th, and a 10th pulse pattern.

19. A battery management system for a vehicle, comprising:
a sensing unit to determine if the battery is fully charged or fully discharged; and
a main control unit (MCU) to generate a charge/discharge pulse pattern waveform comprising a plurality of pulse patterns, to measure a maximum peak voltage value and a minimum peak voltage value of at least one of the plurality of pulse patterns, and to set an average of the measured maximum peak voltage value and the measured minimum peak voltage value to an open circuit voltage (OCV) setting, and to estimate a state of charge (SOC) therefrom.

20. The battery management system of claim 19, wherein the MCU charges the battery to a predetermined level if the battery is fully discharged, and the MCU discharges the battery to the predetermined level if the battery is fully charged.

21. The battery management system of claim 20, wherein the predetermined level is 60% of a previously estimated SOC.

22. The battery management system of claim 20, wherein the MCU generates the charge/discharge pulse pattern waveform after the battery is charged/discharged to the predetermined level.

23. The battery management system of claim 19, wherein the plurality of pulse patterns comprises 10 pulse patterns.

24. The battery management system of claim 23, wherein the average comprises an average of the maximum and minimum peak voltages of a 10th pulse pattern.

25. The battery management system of claim 23, wherein the average comprises an average of the maximum and minimum peak voltages of an 8th, a 9th, and a 10th pulse pattern.

26. The battery management system of claim 19, wherein the MCU generates the charge/discharge pulse pattern waveform while the vehicle is operating.

27. The battery management system of claim 26, wherein the MCU generates the charge/discharge pulse pattern waveform while the vehicle is accelerating.

28. The battery management system of claim 19, wherein the MCU generates the charge/discharge pulse pattern waveform while the battery is under a load.
